(19) United States
(12) Patent Application Publication
(10) Pub. No.: US 2021/0146707 A1
(43) Pub. Date: May 20, 2021

(54) METHOD FOR FORMING STEREOSCOPIC PATTERNS OF PLASTIC FLOORBOARDS

(71) Applicant: Zhejiang Kingdom Plastics Industry Co., Ltd., Jiaxing, Zhenjiang (CN)

(72) Inventors: Huibin DAI, Jiaxing (CN); Peidong ZHAO, Jiaxing (CN); Zhongfei ZHANG, Jiaxing (CN)

(21) Appl. No.: 16/767,904

(22) PCT Filed: Nov. 20, 2019
(86) PCT No.: PCT/CN2019/119623

§ 371 Date: May 28, 2020

(30) Foreign Application Priority Data
Nov. 20, 2019 (CN) PCT/CN2019/119623

(51) Int. Cl. B41M 3/06; B41M 7/00; G03F 7/00

(52) U.S. Cl. CPC B41M 3/06; B41M 7/0045; E04F 15/105; G03F 7/0002; B41M 7/0036

(57) ABSTRACT

A method for forming a stereoscopic pattern of a plastic floorboard, comprising: positioning a base board on a digital printing unit, wherein the base board has an outer surface; using the digital printing unit to print pigment on the outer surface of the base board according to a preset pattern to form a pattern layer, wherein the pattern of the pattern layer corresponds to or does not correspond to the stereoscopic pattern; using a first forming unit to form a protection layer on the pattern layer with a transparent melt plastic raw material; and using a second forming unit to form the stereoscopic pattern having a concave-convex structure on the protection layer.

### TECHNICAL FIELD

This disclosure generally relates to the technical field of floorboards, and more particularly, to a method for forming stereoscopic patterns of plastic floorboards.

### BACKGROUND

As using plastic material instead of natural timbers significantly reduces damage to the environment, the development of plastic floor has become a trend. To make the plastic floor aesthetically appealing, various patterns may be printed on a printing layer. The patterns of conventional plastic floorboards are normally pre-printed on the printing layer, which is roll-pressed into a whole along with a base layer and a wear layer during the subsequent process. The visual effect of the flat pattern printed on the printing layer is poor. To improve this, a stereoscopic pattern may be formed on the wear layer. However, the flat pattern on the printing layer may not accurately correspond to the stereoscopic pattern on the wear layer, resulting in the failure of achieving an integral stereoscopic effect. In addition, the printed pattern on the plastic floorboard is fixed, making the customization of the pattern impossible.

### SUMMARY

The purpose of the present disclosure is to provide a method for forming stereoscopic patterns of plastic floorboards, which designs and forms various patterns according to users' needs, makes the stereoscopic patterns more aesthetically appealing, improves the production efficiency and ensures the stability of quality.

To achieve the above purpose, the present disclosure adopts the following technical solution: a method for forming a stereoscopic pattern of a plastic floorboard, comprising positioning a base board on a digital printing unit, wherein the base board has an outer surface; using the digital printing unit to print pigment on the outer surface of the base board according to a preset pattern to form a pattern layer, wherein the pattern of the pattern layer corresponds to or does not correspond to the stereoscopic pattern; using a first forming unit to form a protection layer on the pattern layer with a transparent melt plastic raw material; and using a second forming unit to form the stereoscopic pattern having a concave-convex structure on the protection layer.

In another preferred embodiment, the plastic material used as the protection layer is a UV coating, a PVC material or a PUR coating.

In another preferred embodiment, using the digital printing unit to print the pigment on the outer surface of the base board according to the preset pattern comprises printing the pigment on the outer surface of the base board a plurality of times to achieve a specific height.

In another preferred embodiment, the first forming unit comprises a second machine body, a second conveying platform arranged on the second machine body, and a coating mechanism. The second conveying platform comprises two conveying wheels, a plurality of rolling wheels and a conveying belt. The coating mechanism is arranged above the second conveying platform and comprises a main roll and an auxiliary roll, and a receiving portion is arranged between the main roll and the auxiliary roll for receiving the melt plastic raw material. In one embodiment, the coating mechanism is controlled by an electrical control system. When the base board is conveyed to a particular position, the melt plastic raw material in the receiving portion is coated on the pattern layer along the rotation of the main roll. Through the auxiliary roll and the main roll that rotate in opposite directions, a coating of the melt plastic raw material becomes more uniform.

In another preferred embodiment, the first forming unit comprises a third conveying platform arranged on the second machine body and a shower-coating mechanism correspondingly arranged above the third conveying platform. The third conveying platform comprises a plurality of conveying wheels capable of propelling the conveying belt to rotate. The lower end of the shower-coating mechanism is provided with a discharging port whose interior allows the melt plastic raw material to flow therein. The melt plastic raw material is vertically discharged from the discharging port in a shower manner. When the base board is conveyed through the lower portion of the shower-coating mechanism, the melt plastic raw material is coated on the pattern layer.

In another preferred embodiment, the second forming unit comprises two roll wheels, and an embossing pattern having a concave-convex structure that is formed on one of the two roll wheels. The concave-convex structure of the embossing pattern is designed to correspond to a particular portion of the pattern layer. After the base board passes through the second forming unit, a stereoscopic pattern with the concave-convex structure is formed on the protection layer.

In another preferred embodiment, the second forming unit is a second coating mechanism arranged on a platform, wherein one end of the second coating mechanism is connected to a source for supplying the melt plastic raw material, and another end of the second coating mechanism outputs the melt plastic raw material. In one embodiment, the second coating mechanism is controlled by an electrical control system. After the protection layer is dried, a stereoscopic pattern with a raised structure is formed on the protection layer through roll-coating or spray-coating.

In another preferred embodiment, the second forming unit is a pressing mechanism, wherein the pressing mechanism comprises a mold frame, an upper mold holder, a lower mold holder and two power sources that are arranged on the mold frame. The mold frame comprises a plurality of guide rods penetrating through a positioning plate located above the guide rods, and a plurality of connecting plates connected to the upper mold holder and the lower mold holder. The two power sources are fixedly arranged on the positioning plate. One end of each power source is provided with a telescopic shaft, and one end of the telescopic shaft is fixedly connected with the outer surface of the upper mold holder. When the two power sources operate, the upper mold holder is propelled to move up and down. A movable mold plate is arranged on the outer surface of the upper mold holder that corresponds to the lower mold holder, and an embossing pattern is formed on the outer surface of the mold plate. The embossing pattern has the concave-convex structure, which is designed to correspond to a particular portion of the pattern layer.

In another preferred embodiment, the digital printing unit comprises a first machine body, a first conveying platform arranged on the first machine body, and a printing mechanism correspondingly arranged above the first conveying platform. The printing mechanism comprises a collecting seat, one end of the collecting seat is connected to a source for supplying the pigment, and another end of the collecting seat is provided with a discharging portion for discharging the pigment. In one embodiment, the printing mechanism is controlled by an electrical control system. When the base board is conveyed to a particular position, the printing mechanism is controlled to print the pigment on the outer surface of the base board through the discharging portion according to the pattern preset in an electrical control system, thereby forming the pattern layer.

In another preferred embodiment, when forming a stereoscopic pattern on the base board by the second forming unit, the base board is positioned at a particular position. A positioning point is pre-arranged at a proper position on the base board, or a plurality of positioning points are arranged on the base board at equal intervals. When a positioning point is detected by the electrical control system, the second forming unit is controlled to form a stereoscopic pattern having a concave-convex structure on the protection layer, and each stereoscopic pattern is formed at a particular position on the corresponding pattern layer through positioning the positioning point.

Through adopting the method of the present disclosure, various patterns may be designed and formed according to users' needs, the stereoscopic patterns become more aesthetically appealing, the production efficiency is improved and the stability of quality is ensured.

### BRIEF DESCRIPTION OF THE FIGURES

FIG. 1 is a plan view illustrating the equipment of an embodiment of the present disclosure.

FIG. 2 is a plan view illustrating the equipment of another embodiment of the present disclosure.

FIG. 3 is a plan view illustrating the equipment of another embodiment of the present disclosure.

FIG. 4 is an enlarged conceptual diagram illustrating the pressing mechanism of the present disclosure.

FIG. 5 is a conceptual diagram illustrating the arrangement of positioning points of the present disclosure.

FIG. 6 is a sectional view illustrating a finished plastic floorboard of the present disclosure.

### DETAILED DESCRIPTION

Figures and detailed embodiments are combined hereinafter to further elaborate the technical solution of the present disclosure.

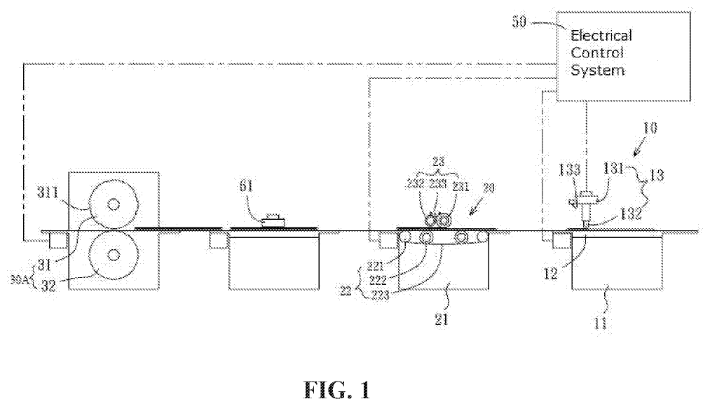

As shown in FIGS. 1-6, a method for forming a stereoscopic pattern of a plastic floorboard comprises machinery equipment including at least one digital printing unit 10, a first forming unit 20 and a second forming unit, wherein the aforesaid equipment is utilized to perform a series of processes to a base board 40, thereby forming the stereoscopic pattern of the plastic floorboard. The aforesaid forming method comprising the steps of:

Step A: taking a base board 40, wherein the base board is normally used as the bottom material of a plastic floorboard, has a blank or plain outer surface 41, and may be continuously extrusion-formed using an extruder or cut into individual boards after machine forming.

Step B: digital printing: positioning the base board 40 on the digital printing unit 10, and printing a pattern layer 42 on the base board 40, wherein the digital printing unit 10 comprises a first machine body 11, a first conveying platform 12 arranged on the first machine body 11, and a printing mechanism 13 correspondingly arranged above the first conveying platform 12, wherein the printing mechanism 13 comprises a collecting seat 131, one end of the collecting seat 131 is connected to a source for supplying the pigment, and another end of the collecting seat 131 is provided with a discharging portion 132 for discharging the pigment, wherein the printing mechanism 13 may be controlled by an electrical control system 50, wherein a sensing unit 133 is arranged at a proper position, and the sensing unit 133 is electrically connected to the electrical control system 50. When the base board 40 is conveyed to a particular position, the electrical control system 50 receives a signal from the sensing unit 133, and the printing mechanism 13 is controlled to print the pigment on the outer surface 41 of the base board 40 through the discharging portion 132 according to the preset pattern in the electrical control system 50. Thus, a pattern layer 42 is formed. When a thicker pattern layer 42 is required, step B may be repeated for 2-3 times to achieve a pattern layer with a specific height.

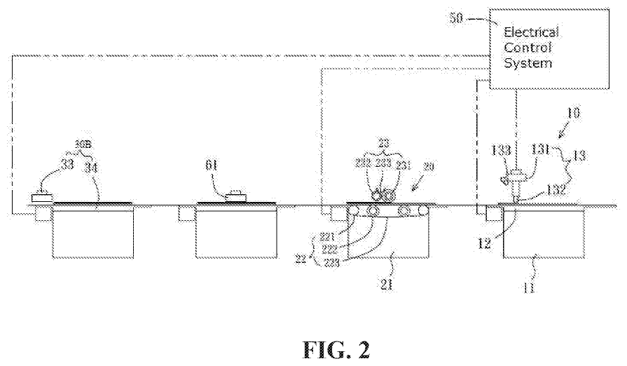

Step C: forming a protection layer 43: forming a protection layer 43 on the pattern layer 42 using a transparent melt plastic raw material by the first forming unit 20, wherein the plastic material used as the protection layer may be a UV coating, a PVC material or a PUR coating. As shown in FIGS. 1-2, the first forming unit 20 comprises a second machine body 21, a second conveying platform 22 arranged on the second machine body 21, and a coating mechanism 23 correspondingly arranged above the second conveying platform 22, wherein the second conveying platform 22 further comprises two conveying wheels 221, a plurality of rolling wheels 222 and a conveying belt 223, wherein the coating mechanism 23 comprises a main roll 231 and an auxiliary roll 232, and a receiving portion 233 is arranged between the two rolls for receiving the melt plastic raw material. During operation, the coating mechanism 23 is controlled by the electrical control system 50. When the base board 40 is conveyed to a particular position, the melt plastic raw material in the receiving portion 233 is coated on the pattern layer 42 along the rotation of the main roll 231. Moreover, through the auxiliary roll 232 and the main roll 231 that rotate in opposite directions, the coating of the melt plastic raw material becomes more uniform. After being coated on the pattern layer 42, the melt plastic raw material may be irradiated by a drying apparatus 61 such as a UV lamp, thus accelerating the drying and hardening of the melt plastic raw material. Furthermore, when a thicker protection layer 43 is required, step C may be repeated for 2-3 times to achieve a protection layer with a specific height.

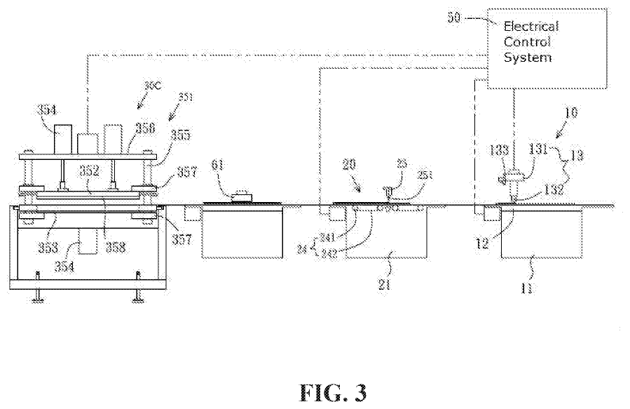

In addition, as shown in FIG. 3, the first forming unit 20 may comprise a third conveying platform 24 arranged on the second machine body 21 and a shower-coating mechanism 25 correspondingly arranged above the third conveying platform 24. The third conveying platform 24 comprises a plurality of conveying wheels 241 capable of propelling the conveying belt to rotate. The lower end of the shower-coating mechanism 25 is provided with a discharging port 251 whose interior allows the melt plastic raw material to flow therein. The melt plastic raw material is vertically discharged from the discharging port 251 in a shower manner. When the base board 40 is conveyed through the lower portion of the shower-coating mechanism 25, the melt plastic raw material is coated on the pattern layer 42. Alternatively, the first forming unit 20 may adopt a digital printer (not shown) to form a protection layer by printing.

Step D: forming a stereoscopic pattern 44: forming a stereoscopic pattern 44 on the protection layer 43 by a second forming unit, thus forming the plastic floorboard with a stereoscopic pattern, wherein the second forming unit may differ in different embodiments.

As illustrated in FIG. 1, a second forming unit 30A may comprise two roll wheels 31 and 32, wherein an embossing pattern 311 having a concave-convex structure is formed on one of the two roll wheels. The concave-convex structure of the embossing pattern 311 is designed to correspond to a particular portion of the pattern layer 42. For instance, when the pattern of the pattern layer 42 is a tree or wood grain, to make a tree burl or the wood grain raise properly, the embossing pattern 311 designed to correspond to the tree burl or wood grain is a recessed structure. According to this design, after the base board 40 passes through the two roll wheels 31 and 32, a stereoscopic pattern 44 with a concave-convex structure is formed on the protection layer 43.

As illustrated in FIG. 2, a second forming unit 30B may be a second coating mechanism 33 arranged on a platform 34, wherein one end of the second coating mechanism 33 is connected to a source for supplying the melt plastic raw material, and another end of the second coating mechanism 33 outputs the melt plastic raw material. The second coating mechanism 33 is controlled by the electrical control system 50. After the protection layer 43 is dried, a stereoscopic pattern 44 with a raised structure is formed on the protection layer 43 through roll-coating or spray-coating.

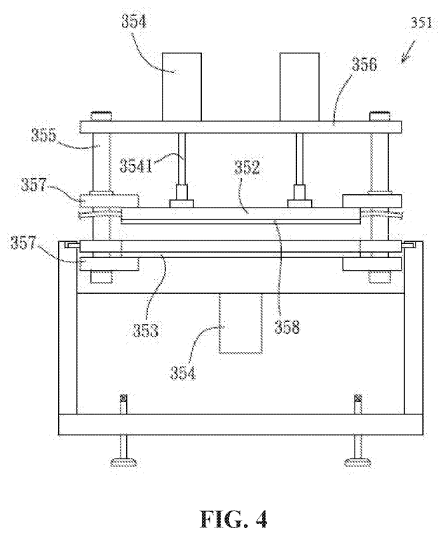

As illustrated in FIG. 3, a second forming unit 30C may be a pressing mechanism. As illustrated in FIG. 4, the pressing mechanism comprises a mold frame 351, an upper mold holder 352, a lower mold holder 353 and two power sources 354. The upper mold holder 352, the lower mold holder 353 and the two power sources 354 are arranged on the mold frame 351. The mold frame 351 comprises a plurality of guide rods 355 penetrating through a positioning plate 356 located above the guide rods 355, and a plurality of connecting plates 357 connected to the upper mold holder 352 and the lower mold holder 353. The two power sources 353 are fixedly arranged on the positioning plate 356. One end of each power source 354 is provided with a telescopic shaft 3541, and one end of the telescopic shaft 3541 is fixedly connected with the outer surface of the upper mold holder 352. According to the aforesaid, when the two power sources 354 work, the upper mold holder 352 is propelled to move up and down. Additionally, a movable mold plate 358 is arranged on the outer surface of the upper mold holder 352 that corresponds to the lower mold holder 353, and an embossing pattern (not shown) is formed on the outer surface of the mold plate 358. The embossing pattern has a concave-convex structure, which is designed to correspond to a particular portion of the pattern layer 42. When the base board 40 is conveyed to or placed at a position under the mold plate 358, the two power sources 354 are initiated to propel the upper mold holder 352, thus enabling the upper mold holder 352 to press downwards. In this way, the mold plate 358 presses the protection layer 43 of the base board 40 so that the stereoscopic pattern 44 is formed.

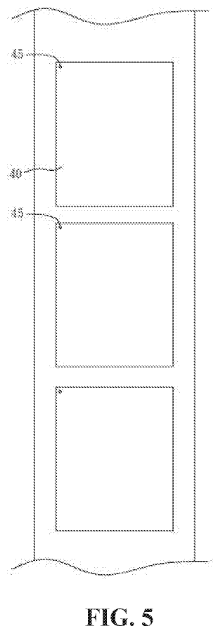

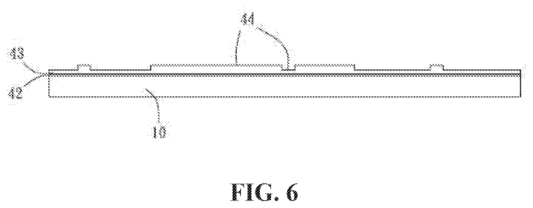

As illustrated in FIG. 5, in actual application of the second forming unit, when forming a stereoscopic pattern 44 on the base board 40 using the roll wheels 31-32 or the pressing mechanism, the base board 40 may be positioned at a particular position and a positioning point 45 may be pre-arranged at a proper position on the base board 40, or a plurality of positioning points are arranged on the base board at equal intervals. As illustrated in FIG. 6, when a positioning point 45 is detected by the electrical control system 50, the second forming unit is initiated to form a stereoscopic pattern 44 having a concave-convex structure on the protection layer 43, and each stereoscopic pattern 44 is formed at a particular position on the corresponding pattern layer 42 through positioning the positioning point 45. Thus, the stereoscopic pattern accurately corresponds to the flat pattern on the pattern layer, achieving an integral stereoscopic visual effect.

The forming method of the present disclosure allows the patterns of the floorboards to be designed and formed according to users' needs, improves the production efficiency and makes the product quality stable.

Additionally, the interior of the upper mold holder 352 and the lower mold holder 353 may be provided with an electric heater to produce heat, or a circulation loop may be installed to guide the hot oil to circulate to produce heat. The heating system transmits the heat to the mold plate 358, which enables the movable pressing mechanism to form an embossing pattern through hot-pressing, and to press the plastic floorboard materials into a whole. Alternatively, in this process, if the temperature of the extrusion-formed base board 40 is high, the hot-pressing is no longer needed. Instead, cooling water may be supplied to the circulation loops of the upper mold holder 352 and the lower mold holder 353 for cooling. The cooled mold plate 358 allows the movable pressing mechanism 30 to form an embossing pattern through cold-pressing, and to presses the plastic floorboard materials into a whole.

Through the aforesaid improvements, various patterns may be designed and formed according to users' needs, the stereoscopic patterns become more aesthetically appealing, the production efficiency is improved, and the stability of quality is ensured.

The above is merely a description of preferred embodiments of the present disclosure, which cannot be understood as a limitation of the claims. Any equivalent modifications of the structure or process described in the specification of the present disclosure shall fall into the scope of the present disclosure.

What is claimed is:

1. A method for forming a stereoscopic pattern of a plastic floorboard, comprising:
positioning a base board on a digital printing unit, wherein the base board has an outer surface;
using the digital printing unit to print pigment on the outer surface of the base board according to a preset pattern to form a pattern layer, wherein the pattern of the pattern layer corresponds to or does not correspond to the stereoscopic pattern;
using a first forming unit to form a protection layer on the pattern layer with a transparent melt plastic raw material; and
using a second forming unit to form the stereoscopic pattern having a concave-convex structure on the protection layer.

2. The method for forming a stereoscopic pattern of a plastic floorboard of claim 1, wherein the plastic material used as the protection layer is a UV coating, a PVC material, or a PUR coating.

3. The method for forming a stereoscopic pattern of a plastic floorboard of claim 1, wherein using the digital printing unit to print the pigment on the outer surface of the base board according to the preset pattern comprises:
printing the pigment on the outer surface of the base board a plurality of times to achieve a specific height.

4. The method for forming a stereoscopic pattern of a plastic floorboard of claim 1, wherein the first forming unit comprises:
a second machine body,
a second conveying platform arranged on the second machine body, wherein the second conveying platform comprises two conveying wheels, a plurality of rolling wheels and a conveying belt, and
a coating mechanism correspondingly arranged above the second conveying platform, wherein the coating mechanism comprises a main roll and an auxiliary roll, wherein a receiving portion is arranged between the main roll and the auxiliary roll for receiving the melt plastic raw material, wherein the coating mechanism is controlled by an electrical control system, wherein when the base board is conveyed to a particular position, the melt plastic raw material in the receiving portion is coated on the pattern layer along the rotation of the main roll, wherein through the auxiliary roll and the main roll that rotate in opposite directions, a coating of the melt plastic raw material becomes more uniform.

5. The method for forming a stereoscopic pattern of a plastic floorboard of claim 4, wherein the first forming unit comprises:
a third conveying platform arranged on the second machine body, wherein the third conveying platform comprises a plurality of conveying wheels capable of propelling the conveying belt to rotate, and
a shower-coating mechanism correspondingly arranged above the third conveying platform, wherein a lower end of the shower-coating mechanism is provided with a discharging port whose interior allows the melt plastic raw material to flow therein, wherein the melt plastic raw material is vertically discharged from the discharging port in a shower manner, wherein when the base board is conveyed through a lower portion of the shower-coating mechanism, the melt plastic raw material is coated on the pattern layer.

6. The method for forming a stereoscopic pattern of a plastic floorboard of claim 1, wherein the second forming unit comprises:
two roll wheels, and
an embossing pattern having the concave-convex structure is formed on one of the roll wheels, wherein the concave-convex structure of the embossing pattern is designed to correspond to a particular portion of the pattern layer, wherein after the base board passes through the second forming unit, the stereoscopic pattern with the concave-convex structure is formed on the protection layer.

7. The method for forming a stereoscopic pattern of a plastic floorboard of claim 1, wherein the second forming unit is a second coating mechanism arranged on a platform, wherein one end of the second coating mechanism is connected to a source for supplying the melt plastic raw material, and another end of the second coating mechanism outputs the melt plastic raw material, wherein the second coating mechanism is controlled by an electrical control system, wherein after the protection layer is dried, the stereoscopic pattern with a raised structure is formed on the protection layer through roll-coating or spray-coating.

8. The method for forming a stereoscopic pattern of a plastic floorboard of claim 1, wherein the second forming unit is a pressing mechanism, wherein the pressing mechanism comprises:
a mold frame, an upper mold holder, a lower mold holder and two power sources that are arranged on the mold frame,
wherein the mold frame comprises a plurality of guide rods penetrating through a positioning plate located above the plurality of guide rods, and a plurality of connecting plates connected to the upper mold holder and the lower mold holder,
wherein the two power sources are fixedly arranged on the positioning plate,
wherein, for each power source of the two power sources, one end of a respective power source is provided with a telescopic shaft, and one end of the telescopic shaft is fixedly connected with an outer surface of the upper mold holder,
wherein when the two power sources operate, the upper mold holder is propelled to move up and down,
wherein a movable mold plate is arranged on the outer surface of the upper mold holder that corresponds to the lower mold holder, and an embossing pattern is formed on the outer surface of the mold plate,
wherein the embossing pattern has the concave-convex structure, which is designed to correspond to a particular portion of the pattern layer.

9. The method for forming a stereoscopic pattern of a plastic floorboard of claim 1, wherein the digital printing unit comprises:
a first machine body,
a first conveying platform arranged on the first machine body, and
a printing mechanism correspondingly arranged above the first conveying platform, wherein the printing mechanism comprises a collecting seat, one end of the collecting seat is connected to a source for supplying the pigment, and another end of the collecting seat is provided with a discharging portion for discharging the pigment, wherein the printing mechanism is controlled by an electrical control system, wherein when the base board is conveyed to a particular position, the printing mechanism is controlled to print the pigment on the outer surface of the base board through the discharging portion according to the preset pattern in the electrical control system.

10. The method for forming a stereoscopic pattern of a plastic floorboard of claim 1, wherein when forming the stereoscopic pattern on the base board by the second forming unit, the base board is positioned at a particular position, wherein a positioning point is pre-arranged at a proper position on the base board, or a plurality of positioning points are arranged on the base board at equal intervals, wherein when a positioning point is detected by an electrical control system, the second forming unit is controlled to form the stereoscopic pattern having the concave-convex structure on the protection layer, and the stereoscopic pattern is formed at a particular position on the corresponding pattern layer through positioning the positioning point.

11. The method for forming a stereoscopic pattern of a plastic floorboard of claim 3, wherein the digital printing unit comprises:
a first machine body,
a first conveying platform arranged on the first machine body, and
a printing mechanism correspondingly arranged above the first conveying platform, wherein the printing mechanism comprises a collecting seat, one end of the collecting seat is connected to a source for supplying the pigment, and another end of the collecting seat is provided with a discharging portion for discharging the pigment, wherein the printing mechanism is controlled by an electrical control system, wherein when the base board is conveyed to a particular position, the printing mechanism is controlled to print the pigment on the outer surface of the base board through the discharging portion according to the preset pattern in the electrical control system.

12. The method for forming a stereoscopic pattern of a plastic floorboard of claim 6, wherein when forming the stereoscopic pattern on the base board by the second forming unit, the base board is positioned at a particular position, wherein a positioning point is pre-arranged at a proper position on the base board, or a plurality of positioning points are arranged on the base board at equal intervals, wherein when a positioning point is detected by an electrical control system, the second forming unit is controlled to form the stereoscopic pattern having the concave-convex structure on the protection layer, and the stereoscopic pattern is formed at a particular position on the corresponding pattern layer through positioning the positioning point.

13. The method for forming a stereoscopic pattern of a plastic floorboard of claim 7, wherein when forming the stereoscopic pattern on the base board by the second forming unit, the base board is positioned at a particular position, wherein a positioning point is pre-arranged at a proper position on the base board, or a plurality of positioning points are arranged on the base board at equal intervals, wherein when a positioning point is detected by an electrical control system, the second forming unit is controlled to form the stereoscopic pattern having the concave-convex structure on the protection layer, and the stereoscopic pattern is formed at a particular position on the corresponding pattern layer through positioning the positioning point.
